(19) United States
(12) Patent Application Publication
(10) Pub. No.: US 2003/0027406 A1
(43) Pub. Date: Feb. 6, 2003

(54) Gettering of SOI wafers without regions of heavy doping

(76) Inventor: Farris D. Malone, Richardson, TX (US)

Correspondence Address: TEXAS INSTRUMENTS INCORPORATED, P O BOX 655474, M/S 3999, DALLAS, TX, 75265

(21) Appl. No.: 09/920,577

(22) Filed: Aug. 1, 2001

(51) Int. Cl. H01L 21/322

(52) U.S. Cl. 438/471

(57) ABSTRACT

The invention describes a method for gettering silicon on insulator wafers without forming regions of heavy doping. Silicon germanium layers (201, 304) are formed beneath silicon layers (200, 305) such that dislocations will form in the silicon germanium layers. These dislocations will serve to getter impurities.

### FIELD OF THE INVENTION

The invention is generally related to the field of semiconductor devices and fabrication and more specifically to a method for forming silicon on insulator wafers.

### BACKGROUND OF THE INVENTION

Silicon on insulator (SOI) is finding increasing usage as a substrate on which integrated circuits are fabricated. A SOI substrate comprises a silicon wafer with a buried insulator layer. A typical SOI substrate is shown in FIG. 1. A buried insulator layer 101 is formed on a silicon wafer 100. This buried insulator layer 101 usually comprises silicon oxide or other suitable dielectric material. Silicon layers 102 and 103 are formed on the buried insulator layer 101 to complete the formation of the SOI substrate. A number of different techniques such as high energy oxygen implantation (SIMOX) and wafer bonding can be used to form the SOI substrates. The active devices are usually fabricated in a silicon epitaxial layer 103 which is grown on the silicon layer 102 which is adjacent to the buried insulator layer 101. In many instances the silicon layer 102 which is adjacent to the buried insulator layer 101 is fairly heavily doped with boron, arsenic, and/or phosphorous and acts as a gettering layer for impurities which may be introduced into the wafer during epitaxial layer growth and subsequent device fabrication. Without this gettering of impurities the electrical properties of the devices fabricated in the epitaxial layer will deteriorate. For example the voltage required for dielectric breakdown of the gate dielectric in the MOS devices will decrease. In addition the breakdown voltage and reverse leakage current of diodes fabricated in the epitaxial layers will decrease and increase respectively.

The introduction of the heavily doped layer 102 in SOI substrates is therefore required for the fabrication of high performance, reliable, electronic devices in the epitaxial layer 103. For some applications diodes with high breakdown voltages are required. A high diode breakdown voltage depend on a number of properties including the doping concentration of the epitaxial layer. A high diode breakdown voltage will typically require a fairly lightly doped epitaxial layer. During the processing of the integrated circuit the SOI substrate will be exposed to a number of high temperature cycles. High temperature cycling will result in the out-diffusion of dopants from the heavily doped silicon layer 102 into the epitaxial layer 103. This dopant diffusion will serve to limit the minimum doping level which can be achieved in the epitaxial layer 103 and therefore limit the breakdown voltage obtainable. There is therefore a need for a method that will allow for the gettering of impurities in SOI substrates without limiting the dopant levels obtainable in the epitaxial layers.

### SUMMARY OF THE INVENTION

The present invention describes a method for gettering SOI wafers without regions of heavy doping. In the first embodiment a silicon germanium layer is formed on a silicon substrate and a silicon layer is formed on the silicon germanium layer. The silicon layer is oxidized and bonded to a second silicon oxide layer on a second silicon substrate. The silicon substrate is polished to form a silicon on insulator substrate with a silicon germanium layer to getter impurities.

In a further embodiment of the instant invention, a silicon germanium layer is formed on a silicon on insulator substrate. A silicon layer is formed on the silicon germanium layer in which electronic devices can be fabricated. The underlying silicon germanium layer will act to getter impurities.

### BRIEF DESCRIPTION OF THE DRAWINGS

In the drawings:

FIG. 1 is a cross-sectional diagrams showing the prior art.

FIGS. 2(a)-(d) are cross-sectional diagrams illustrating an embodiment of the instant invention.

FIGS. 3(a)-(b) are cross-sectional diagrams illustrating an embodiment of the instant invention.

### DETAILED DESCRIPTION OF THE INVENTION

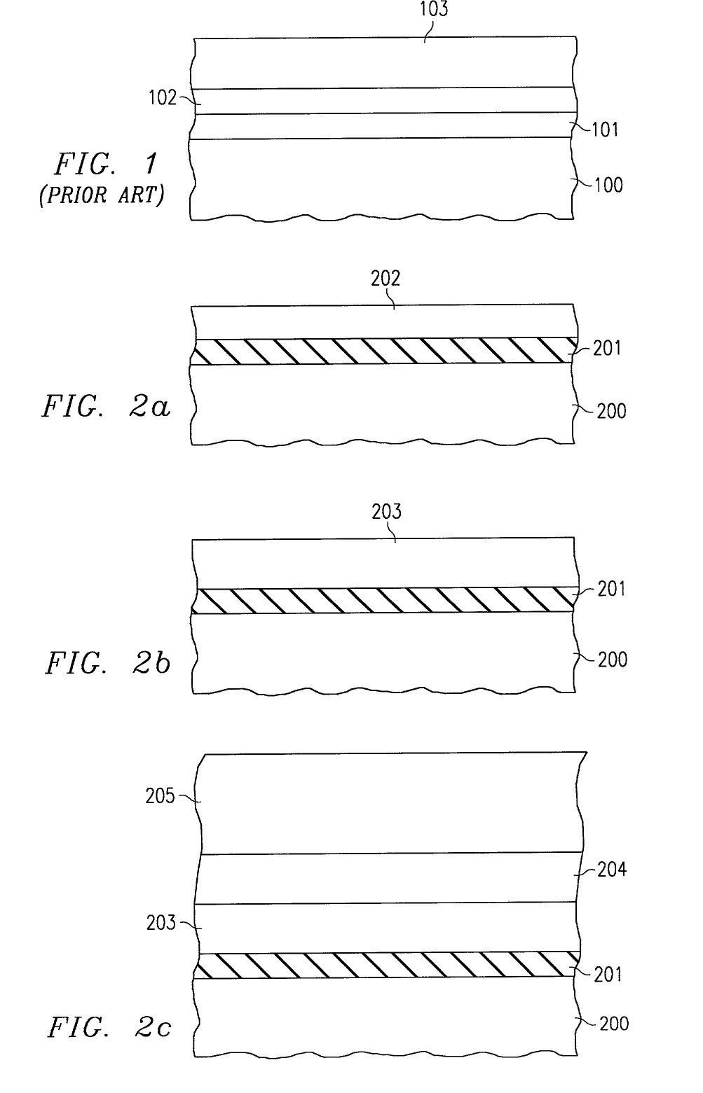

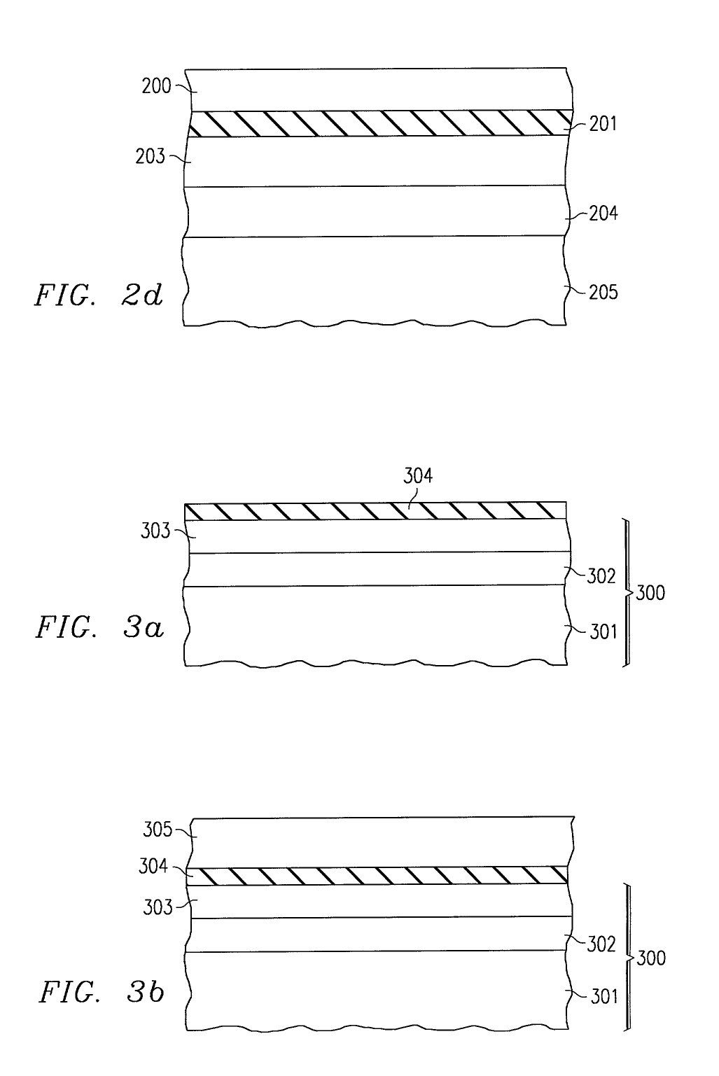

The invention will now be described with reference to FIGS. 2 and 3. It will be apparent to those of ordinary skill in the art that the benefits of the invention can be applied to other structures where a silicon on insulator substrate is utilized.

Shown in FIG. 2(a) is a silicon wafer 200 on which a layer of silicon germanium 201 is formed. The thickness of the silicon germanium layer 201 is such that dislocations will form in the silicon germanium layer 201 during subsequent processing. The germanium concentration in the silicon germanium layer can vary from 0 to 100 atomic percent but in a first embodiment of the instant invention will have a lower limit of 10 atomic percent. Therefore in the first embodiment of the instant invention the concentration of germanium in the silicon germanium layer will be between 10 and 100 atomic percent. The silicon germanium layer 201 can be formed using known semiconductor processing technology. Following the formation of the silicon germanium layer 201 a silicon layer 202 is formed on the silicon germanium layer. The silicon layer 202 can be formed using known semiconductor processing technology.

Following the formation of the silicon layer 202, the structure is exposed to an oxidizing ambient sufficient to oxidize the silicon layer 202 to form a layer of silicon oxide 203. This oxidation process can comprise heating the structure to a temperature above 600° C. and exposing the silicon layer 202 to oxygen. In a further embodiment of the instant invention the entire silicon layer 202 is converted to silicon oxide 203. This thickness of the silicon layer should be such that at the end of the oxidation process dislocations will form in the silicon germanium layer.

Following the formation of the silicon oxide layer 203 illustrated in FIG. 2(c), the silicon oxide layer 203 is bonded to a second silicon oxide layer 204 which was formed on a second silicon wafer 205. The bonding of the silicon oxide layers 203 and 204 is performed using known silicon wafer bonding technology. The silicon oxide layer 204 can be formed on the silicon wafer 205 by heating the silicon wafer 205 to temperatures above 600° C. and exposing the surface of the wafer to an oxidizing ambient. The bonded structure of FIG. 2(c) therefore comprises a silicon substrate 200, a silicon germanium layer 201, a silicon oxide layer 203 bonded to a second silicon oxide layer 204, and a second silicon substrate 205.

Shown in FIG. 2(d) is the completed structure. The structure of FIG. 2(c) is inverted and the thickness of the silicon wafer 200 is reduced by polishing, chemical etching of some other suitable technique. The electronic devices that will comprise the integrated circuit will now be fabricated in the silicon wafer 200 and the second silicon wafer 205 will serve as the substrate. If necessary an addition silicon epitaxial layer can be formed on the surface of silicon wafer 200. If this additional silicon epitaxial layer is formed the electronic devices will be formed in the additional epitaxial layer. The silicon germanium layer 201 which contains the dislocations will now be beneath the electronic devices and will serve to getter impurities from these electronic devices.

Shown in FIGS. 3(a) and 3(b) are further embodiments of the instant invention. As illustrated in FIG. 3(a) a silicon on insulator substrate 300 is provided. This silicon on insulator substrate can be formed by any number of known methods such as oxygen implantation (SIMOX), and wafer bonding. The silicon on insulator substrate will comprise a silicon substrate 301, a silicon oxide layer 302, and a silicon layer 303. A silicon germanium layer 304 is formed on the surface of the silicon layer 303. The germanium concentration in the silicon germanium layer 304 can vary between 0 to 100 atomic percent but is most preferably between 10 to 100 atomic percent. The thickness of the silicon germanium layer must be such that dislocations will form in silicon germanium layer 304 when a second silicon layer 305 is subsequently formed on the silicon germanium layer 304. The completed structure is shown in FIG. 3(b) where the second silicon layer 305 is shown on the silicon germanium layer 304. The thickness of the second silicon layer 305 must be such that dislocations will form in the silicon germanium layer 304. The second silicon layer 305 can be formed using known methods for forming silicon layers in semiconductor technology. If necessary an addition silicon epitaxial layer can be formed on the second silicon layer 305. If this additional silicon epitaxial layer is formed the electronic devices will be formed in the additional epitaxial layer. Electronic devices can therefore be formed in the second silicon layer 305 or in an additional silicon epitaxial layer (if present) where the underlying silicon germanium layer 304 will act to getter impurities.

While this invention has been described with reference to illustrative embodiments, this description is not intended to be construed in a limiting sense. Various modifications and combinations of the illustrative embodiments, as well as other embodiments of the invention will be apparent to persons skilled in the art upon reference to the description. It is therefore intended that the appended claims encompass any such modifications or embodiments.

We claim:

1. A method for gettering silicon on insulator wafers, comprising:
providing a silicon on insulator substrate comprising a first silicon substrate, a silicon oxide layer on said first silicon substrate, and a second silicon layer on said silicon oxide layer;
forming a silicon germanium layer on said second silicon layer; and
forming a third silicon layer on said silicon germanium layer such that dislocation are formed in said silicon germanium layer.

2. The method of claim 1 wherein said silicon germanium layer comprises a germanium concentration between 10 to 100 atomic percent.

3. The method of claim 1 further comprising forming a silicon epitaxial layer on said third silicon layer.

4. A method for forming silicon on insulator substrates, comprising:
providing a first silicon wafer and a second silicon wafer;
forming a silicon germanium layer on said first silicon wafer;
forming a first silicon layer on said silicon germanium layer;
converting said first silicon layer to a first silicon oxide layer by heating said first silicon wafer and exposing said first silicon wafer to an oxidizing ambient;
forming a second silicon oxide layer on said second silicon wafer;
bonding said first silicon oxide layer and said second silicon oxide layer; and
reducing the thickness of said first silicon wafer.

5. The method of claim 3 wherein said silicon germanium layer comprises a germanium concentration between 10 to 100 atomic percent.

6. The method of claim 3 wherein a silicon epitaxial layer is formed on said first silicon wafer.
